(19) United States
(12) Patent Application Publication
(10) Pub. No.: US 2022/0293824 A1
(43) Pub. Date: Sep. 15, 2022

(54) ULTRAVIOLET LED DEVICE

(71) Applicant: NINGBO SUNPU LED CO., LTD., Ningbo, Zhejiang (CN)

(72) Inventors: Yaohua ZHANG, Ningbo, Zhejiang (CN); Yuanbao DU, Ningbo, Zhejiang (CN); Xiaoning CAI, Ningbo, Zhejiang (CN); Fusheng CHEN, Ningbo, Zhejiang (CN); Qinghao ZHANG, Ningbo, Zhejiang (CN)

(73) Assignee: NINGBO SUNPU LED CO., LTD., Ningbo, Zhejiang (CN)

(21) Appl. No.: 17/635,391

(22) PCT Filed: Jul. 3, 2020
(86) PCT No.: PCT/CN2020/100110

§ 371 Date: Feb. 15, 2022

(30) Foreign Application Priority Data
Apr. 17, 2020 (CN) 202010305693.0
Apr. 17, 2020 (CN) 202020578530.5

(51) Int. Cl. H01L 33/46; H01L 33/58; H01L 33/62

(52) U.S. Cl. CPC H01L 33/46; H01L 33/58; H01L 33/62

(57) ABSTRACT

An ultraviolet LED device, including: a substrate, where a pad is located at an upper surface of the substrate, and another pad is located at a lower surface of the substrate; an ultraviolet LED chip; a chip fixing portion, configured to attach the ultraviolet LED chip to the pad; a high-reflective layer, located at an upper surface of the pad and surrounding the chip fixing portion; a cover lens attached to the substrate, where the cover lens and the substrate form a cavity for accommodating the ultraviolet LED chip. A utilization rate of the ultraviolet light is improved, a manufacture process is simplified, and a cost is reduced for ultraviolet LED devices.

The present disclosure claims priority to Chinese Patent Application No. 202010305693.0, titled “ULTRAVIOLET LED DEVICE” and Chinese Patent Application No. 202020578530.5, both titled “ULTRAVIOLET LED DEVICE”, filed on Apr. 17, 2020 with the China National Intellectual Property Administration, which are incorporated herein by reference in its entirety.

### FIELD

The present disclosure relates to the technical field of LED, and in particular, to an ultraviolet LED device.

### BACKGROUND

Generally, an ultraviolet light emitting diode (LED) refers to a LED of which a central wavelength is below 400 nm. The ultraviolet LEDs are widely used in the fields such as biomedicine, anti-counterfeiting, purification (of water, air, etc.), computer data storage, and military applications.

A conventional ultraviolet LED device adopts a structure in which a substrate is attached to a frame carrying a flat quartz glass, as shown in FIG. 1. The attachment between the frame and the substrate is implemented in two manners. In a first manner, a ceramic frame is attached to the substrate via an adhesive. In a second manner, a pure copper frame is fabricated layer by layer through electroplating, and then is attached to the substrate to form an integrated structure. Both manners feature a complicated process and a high cost. Furthermore, it is necessary to plate gold or silver on surfaces of the substrate and the frame to prevent copper pads on the substrate from being oxidized. As shown in FIG. 2, reflectivity of gold or silver is rather low for an ultraviolet light. Hence, a large proportion of the ultraviolet light is absorbed by gold or silver located at an internal surface of the LED device, or cannot follow an angle that enables the ultraviolet light to reach the light-emitting surface, resulting in a huge waste of resources and a low performance.

Therefore, how to address the above technical issue is a great concern of those skilled in the art.

### SUMMARY

An objective of the present disclosure is to provide an ultraviolet LED device, which improves reflectivity on, and a utilization rate of, ultraviolet light in ultraviolet LED devices and simplifies a manufacturing process.

In order to address the above technical issue, an ultraviolet LED device is provided according to embodiments of the present disclosure. The ultraviolet LED device includes: a substrate, where a pad is located at an upper surface of the substrate, and another pad is located at a lower surface of the substrate; an ultraviolet LED chip; a chip fixing portion, configured to attach the ultraviolet LED chip to the pad; a high-reflective layer, located at an upper surface of the pad and surrounding the chip fixing portion; a cover lens attached to the substrate, where the cover lens and the substrate form a cavity for accommodating the ultraviolet LED chip.

Optionally, the high-reflective layer is made of aluminum or polytetrafluoroethylene.

Optionally, the cover lens has a spherical surface.

Optionally, the ultraviolet LED chip is an upright-mounted chip, and the ultraviolet LED device further includes a wire configured to connect the ultraviolet LED chip and the pad.

Optionally, the wire is made of gold.

Optionally, the substrate is an aluminum nitride ceramic substrate or an alumina ceramic substrate.

Optionally, the cavity is filled with nitrogen or an inert gas.

Optionally, the cover lens is made of quartz glass.

Optionally, the ultraviolet LED device further includes: a first eutectic solder layer, located at the upper surface of the substrate and surrounding the pad; a support, attached to the first eutectic solder layer through eutectic soldering, where the high-reflective layer is further located at an inner surface of the support; and a second eutectic solder layer, located at an upper surface of the support; where the cover lens is a plate lens which is attached to the second eutectic solder layer through eutectic soldering.

Optionally, the plate lens is made of a glass of JGS2 grade.

The ultraviolet LED device according to embodiments of the present disclosure includes: the substrate of which the upper surface and the lower surface are provided with the pads, the ultraviolet LED chip, the chip fixing portion configured to attach the ultraviolet LED chip to the pad located at the upper surface of the substrate, the high-reflective layer located at the upper surface of the pad and surrounding the chip fixing portion, and the cover lens attached to the substrate, where the cover lens and the substrate form the cavity for accommodating the ultraviolet LED chip.

Hence, the ultraviolet LED device according to embodiments the present disclosure has the chip fixing portion provided on the pad at the upper surface of the substrate, and the chip fixing portion is configured to fix the ultraviolet LED chip. The high-reflective layer is provided at the upper surface of the pad and surrounds the chip fixing portion, and hence a layer of plated gold is not necessary, which effectively improves reflectivity on a ultraviolet light and reduces absorption of the ultraviolet light in the ultraviolet LED device. The lens serves as a cover and is directly attached to the substrate to form the cavity accommodating the LED chip. Thereby, it is unnecessary to dispose a frame on the substrate. Absorption of the ultraviolet light due to the frame is avoided, and an ultraviolet light that would have irradiated the frame in conventional technology is induced outside through the cover lens. A utilization rate of the ultraviolet light is improved, a manufacture process is simplified, and a cost is reduced for ultraviolet LED devices.

### BRIEF DESCRIPTION OF THE DRAWINGS

In order to more clearly illustrate technical solutions in embodiments of the present disclosure or in the conventional technology, drawings used in the description of the embodiments or the conventional technology are introduced briefly hereinafter. Apparently, the drawings described in the following illustrate some embodiments of the present disclosure; other drawings may be obtained by those ordinarily skilled in the art based on these drawings without any creative efforts.

FIG. 1 is a schematic structural diagram of an ultraviolet LED device in conventional technology.

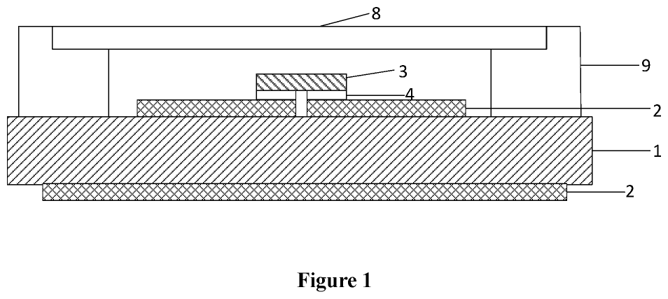

FIG. 2 is a graph of reflectivity of different metals with respect to light wavelength.

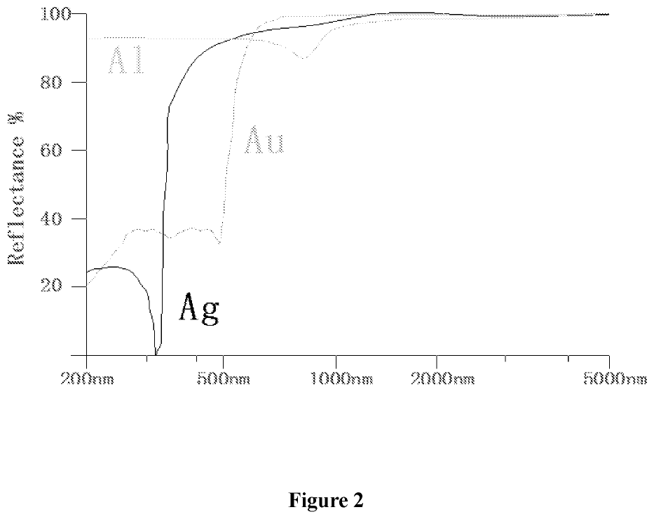

FIG. 3 is a schematic structural diagram of an ultraviolet LED device according to an embodiment of the present disclosure.

FIG. 4 is a top view of an ultraviolet LED device according to an embodiment of the present disclosure.

FIG. 5 is a schematic structural diagram of an ultraviolet LED device according to an embodiment of the present disclosure.

FIG. 6 is a top view of an ultraviolet LED device according to another embodiment of the present disclosure.

FIG. 7 is a schematic structural diagram of an ultraviolet LED device according to another embodiment of the present disclosure.

Reference signs:

| | |
|---|---|
| 1: substrate; | 2: pad; |
| 3: ultraviolet LED chip; | 4: chip fixing portion; |
| 5: high-reflective layer; | 6: cover lens; |
| 7: cavity; | 8: flat lens; |
| 9: frame; | 10: first eutectic solder layer; |
| 11: support; | 12: second eutectic solder layer; |
| 13: plate lens. | |

### DETAILED DESCRIPTION

In order to facilitate those skilled in the art understand technical solutions of the present disclosure, hereinafter technical solutions in embodiments of the present disclosure are described clearly and completely in conjunction with the drawings in embodiments of the present closure. Apparently, the described embodiments are only some rather than all of the embodiments of the present disclosure. Any other embodiments obtained based on the embodiments of the present disclosure by those skilled in the art without any creative effort fall within the scope of protection of the present disclosure.

Hereinafter various details are illustrated in description for comprehensive understanding of the present disclosure. The present disclosure may be implemented in other embodiments. Those skilled in the art can modify specific embodiments without departing from the concept of the present disclosure, and hence embodiments disclosed herein should not be construed to limit the present disclosure.

As stated in the Background, a conventional ultraviolet LED device adopts a structure in which a substrate is attached to a frame, and a manufacture process is complicated. It is necessary to plate gold or silver on surfaces of the substrate and the frame. A large proportion of the ultraviolet light is absorbed by gold or silver located at an internal surface of the LED device, or cannot follow an angle that enables the ultraviolet light to reach the light-emitting surface, resulting in a huge waste of resources and a low performance.

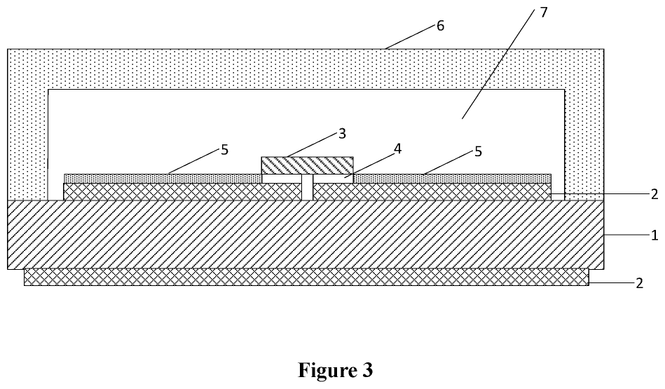

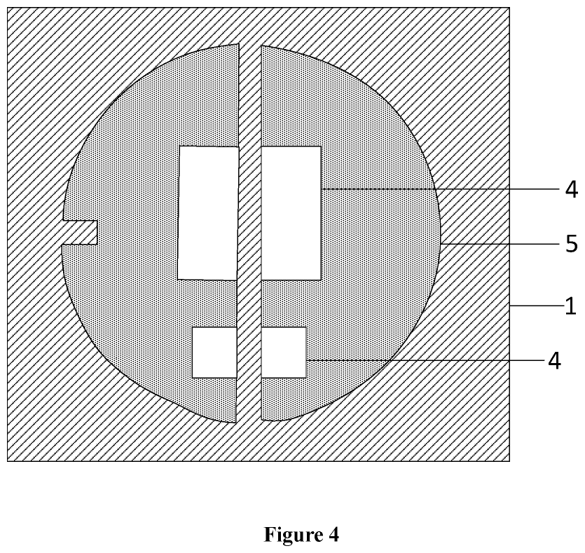

In view of the above, an ultraviolet LED device is provided according to an embodiment of the present disclosure. Reference is made to FIGS. 3 and 4. FIG. 3 is schematic structural diagram of an ultraviolet LED device according to an embodiment of the present disclosure, and FIG. 4 is a top view of an ultraviolet LED device according to an embodiment of the present disclosure.

The ultraviolet LED device includes a substrate 1, an ultraviolet LED chip 3, a chip fixing portion 4, a high-reflective layer 5, and a cover lens 6 that has a shape like a cup. A pad 2 is located at an upper surface of the substrate, and another pad 2 is located at a lower surface of the substrate 1. The chip fixing portion 4 is configured to attach the ultraviolet LED chip 3 to the pad 2 at the upper surface of the substrate 1. The high-reflective layer 5 is located at an upper surface of the pad 2, and surrounds the chip fixing portion 4. The cover lens 6 is attached to the substrate 1, and the cover lens 6 and the substrate 1 form a cavity 7 for accommodating the ultraviolet LED chip 3.

The pad 2, on which the high-reflective layer 5 is located, refers to the pad at the upper surface of the substrate 1. That is, the high-reflective layer 5 is disposed all over the upper surface of the pad 2 except an area in which the chip fixing portion 4 is located, so as to avoid absorption of ultraviolet light. Thereby, reflectivity for an ultraviolet light can be increased while ensuring a performance and reliability of the ultraviolet LED device. Generally, the pad 2 is made of copper.

The high-reflective layer 5 refers to a layer having reflectivity of more than 80% for an ultraviolet light. In a preferable embodiment, the high-reflective layer 5 is made of aluminum or polytetrafluoroethylene, which can reduce a cost of the ultraviolet LED device.

The cover lens 6 is attached to the upper surface of the substrate 1 via an adhesive medium. The adhesive medium is not specifically limited herein, as long as capable to implement the attachment between the cover lens 6 and the substrate 1 to form the closed cavity 7. For example, the adhesive medium may be silica gel, epoxy glue, or the like.

A size of the chip fixing portion 4 is determined according to a size of the ultraviolet LED chip 3, that is, the chip fixing portion 4 is consistent with the ultraviolet LED chip 3 in size. The ultraviolet LED chip 3 may include a substrate layer, a buffer layer, an N-type AlGaN layer, a negative electrode, a quantum well layer, a P-type AlGaN layer, a contact layer, and a positive electrode. A specific structure of the ultraviolet LED chip 3 is well known to those skilled in the art and would not be described herein in detail.

In one embodiment, the ultraviolet LED chip 3 is a flip-chip LED chip, and the chip fixing portion 4 is made of gold to increase firmness of the attachment between the ultraviolet LED chip 3 and the pad 2. In another embodiment, the ultraviolet LED chip 3 is an upright-mounted chip, and the ultraviolet LED device further includes a wire configured to connecting the ultraviolet LED chip 3 and the pad 2 at the upper surface of the substrate 1. The wire may implement electrical connection between a positive electrode and/or a negative electrode, of the ultraviolet LED chip 3, and the pad 2.

In one embodiment, the wire is made of gold. A material is not limited herein. Alternatively, the wire may be made of silver, copper, an alloy, or the like.

In an embodiment, the substrate 1 is an aluminum nitride ceramic substrate 1, and present disclosure is not limited thereto. In another embodiment, the substrate 1 may be an alumina ceramic substrate 1.

In an e, the cover lens 6 is any one of a quartz glass cover lens, a soda lime glass cover lens, and a borosilicate glass cover lens.

The ultraviolet LED device according to embodiments the present disclosure has the chip fixing portion 4 provided on the pad 2 at the upper surface of the substrate 1, and the chip fixing portion 4 is configured to fix the ultraviolet LED chip 3. The high-reflective layer 5 is provided at the upper surface of the pad 2 and surrounds the chip fixing portion 4, and hence a layer of plated gold is not necessary, which effectively improves reflectivity on a ultraviolet light and reduces absorption of the ultraviolet light in the ultraviolet LED device. The lens 6 serves as a cover and is directly attached to the substrate 1 to form the cavity 7 accommodating the LED chip. Thereby, it is unnecessary to dispose a frame on the substrate 1. Absorption of the ultraviolet light due to the frame is avoided, and an ultraviolet light that would have irradiated the frame in conventional technology is induced outside through the cover lens 6. A utilization rate of the ultraviolet light is improved, a manufacture process is simplified, and a cost is reduced for the ultraviolet LED device.

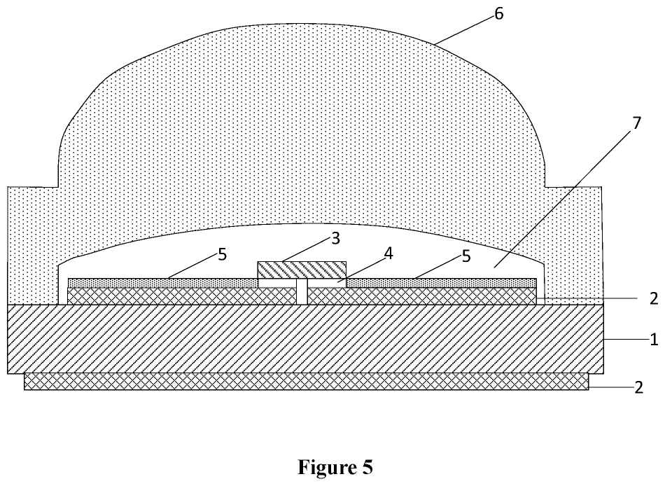

In an embodiment based on any foregoing embodiment, the cover lens 6 has a spherical surface, and an ultraviolet light can exit under different angles. Another structure of an ultraviolet LED device may refer to FIG. 5.

In an embodiment based on any foregoing embodiment, the cavity 7 is filled with nitrogen or an inert gas, in order to protect the ultraviolet LED chip 3 and prolong a service life of the ultraviolet LED device. A type of inert gas is not specifically limited herein and may depend on actual situations. For example, the inert gas may be helium or argon.

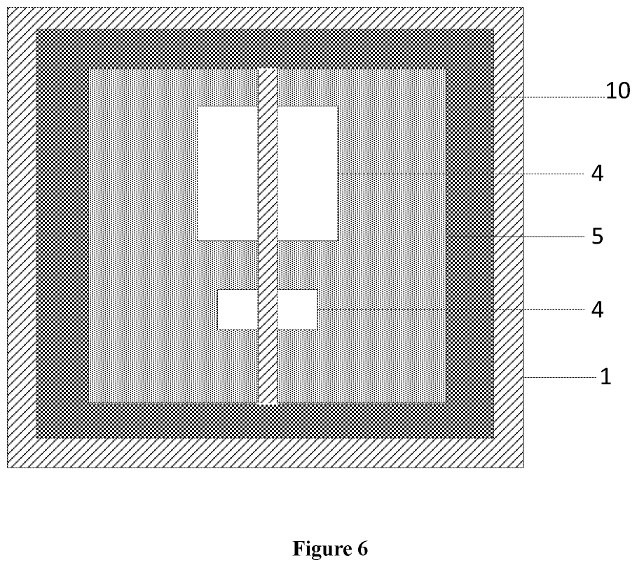

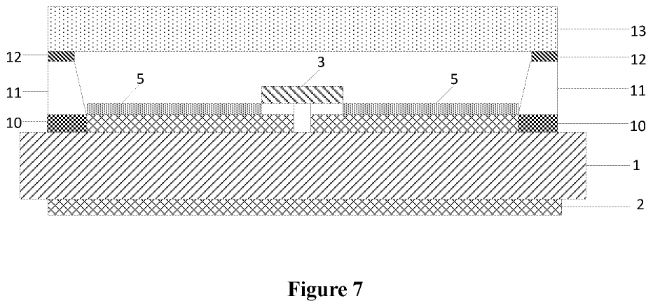

Reference is made to FIGS. 6 and 7. FIG. 6 is a top view of an ultraviolet LED device according to another embodiment of the present disclosure, and FIG. 7 is a schematic structural diagram of an ultraviolet LED device according to another embodiment of the present disclosure.

In an embodiment based on any foregoing embodiment, the ultraviolet LED device further includes a first eutectic solder layer 10, a support 11, and a second eutectic solder layer 12. The first eutectic solder layer 10 is at the upper surface of the substrate 1 and surrounding the pad 2 at the upper surface of the substrate 1. The support 11 is attached to the first eutectic solder layer 10 through eutectic soldering, and the high-reflective layer is further located at an inner surface of the support 11. The second eutectic solder layer 12 is located at an upper surface of the support 11. The cover lens 6 is a plate lens 13 which is attached to the second eutectic solder layer 12 through eutectic soldering.

In an embodiment, the high-reflective layer at the upper surface of the pad may have a square shape.

The high-reflective layer is further disposed on the inner surface of the support 11, that is, an aluminum layer or a polytetrafluoroethylene layer is located at the inner surface of the support 11. The high-reflective layer, including the part at the upper surface of the pad, forms a reflective cavity to enhance reflection for ultraviolet light. A reflection angle formed by the inner surface of the support 11 is not specifically limited herein, and may be determined according to a requirement on an exit angle of the light.

In an embodiment, the support 11 is made of silicon.

In this embodiment, the support 11 and the substrate are bonded via the first eutectic solder layer 10, and the support 11 and the plate lens 13 are bonded the second eutectic solder layer 12. Thereby, packaging is achieved, sealing and reliability is improved, and the service life is prolonged for the ultraviolet LED device.

In a preferable embodiment, the plate lens 13 is made of a glass of JGS2 grade. Using the JGS2 glass lens is capable to reduce absorption of ultraviolet light. Compared with traditional ultraviolet LED devices, reflectivity on the ultraviolet light and a utilization rate of the ultraviolet light can be increased by more than 50%.

The embodiments of the present disclosure are described in a progressive manner, and each embodiment places emphasis on the difference from other embodiments. Therefore, one embodiment can refer to other embodiments for the same or similar parts. Since the apparatuses disclosed in the embodiments correspond to the methods disclosed in the embodiments, the description of the apparatuses is simple, and reference may be made to the relevant part of the methods.

Hereinabove the ultraviolet LED device in embodiments of the present disclosure has been described in details. Specific examples are used to illustrate the principle and implementation of the present disclosure. The description of the above examples is merely intended for understanding a method and a core concept of the present disclosure better. It should be noted that those skilled in the art can make several improvements and modifications on the present disclosure without departing from the principle concept of the present disclosure, and these improvements and modifications also fall within the protection scope defined by the claims of the present disclosure.

1. An ultraviolet LED device, comprising:
a substrate, wherein a pad is located at an upper surface of the substrate, and another pad is located at a lower surface of the substrate
an ultraviolet LED chip;
a chip fixing portion, configured to attach the ultraviolet LED chip to the pad;
a reflective layer, located at an upper surface of the pad and surrounding the chip fixing portion;
a cover lens attached to the substrate, wherein the cover lens and the substrate form a cavity for accommodating the ultraviolet LED chip.

2. The ultraviolet LED device according to claim 1, wherein the reflective layer is made of aluminum or polytetrafluoroethylene.

3. The ultraviolet LED device according to claim 1, wherein the cover lens has a spherical surface.

4. The ultraviolet LED device according to claim 1, wherein:
the ultraviolet LED chip is an upright-mounted chip, and
the ultraviolet LED device further comprises a wire configured to connect the ultraviolet LED chip and the pad.

5. The ultraviolet LED device according to claim 4, wherein the wire is made of gold.

6. The ultraviolet LED device according to claim 1, wherein the substrate is an aluminum nitride ceramic substrate or an alumina ceramic substrate.

7. The ultraviolet LED device according to claim 1, wherein the cavity is filled with nitrogen or an inert gas.

8. The ultraviolet LED device according to claim 1, wherein the cover lens is made of quartz glass.

9. The ultraviolet LED device according to claim 1, further comprising:
a first eutectic solder layer, located at the upper surface of the substrate and surrounding the pad;
a support, attached to the first eutectic solder layer through eutectic soldering, wherein the reflective layer is further located at an inner surface of the support; and
a second eutectic solder layer, located at an upper surface of the support;
wherein the cover lens is a plate lens which is attached to the second eutectic solder layer through eutectic soldering.

10. The ultraviolet LED device according to claim 9, wherein the plate lens is made of a glass of JGS2 grade.
